(19) United States
(12) Patent Application Publication
(10) Pub. No.: US 2024/0412974 A1
(43) Pub. Date: Dec. 12, 2024

(54) METHOD OF FORMING EPITAXIAL SEMICONDUCTOR LAYER AND METHOD OF MANUFACTURING SEMICONDUCTOR DEVICE USING THE SAME

(71) Applicant: RNR LAB INC., Gyeonggi-do (KR)

(72) Inventor: Jeong Do Ryu, Seoul (KR)

(21) Appl. No.: 18/688,833

(22) PCT Filed: Sep. 1, 2022
(86) PCT No.: PCT/KR2022/013088

§ 371 Date: Mar. 4, 2024

(30) Foreign Application Priority Data
Sep. 7, 2021 (KR) 10-2021-0119365

(51) Int. Cl. H01L 21/268; H01L 21/02; H01L 21/20; H01L 29/66

(52) U.S. Cl. CPC H01L 21/268; H01L 21/02381; H01L 21/02428; H01L 21/02491; H01L 21/02639; H01L 21/2011; H01L 29/66795

(57) ABSTRACT

The present disclosure provides a method for forming an epitaxial semiconductor layer including a step for providing a crystallization base member having a single crystal structure; a step for forming a semiconductor layer having one of an amorphous structure and a polycrystalline structure in contact with the crystallization base member; a step for forming a heating layer which may be heated by a laser on the semiconductor layer; a step for melting the semiconductor layer by heating the heating layer by irradiating a laser to the heating layer; and a step for forming a single crystallized epitaxial semiconductor layer from the semiconductor layer through single crystallization of the semiconductor layer according to the single crystalline structure of the crystallization base member by cooling the molten semiconductor layer.

### TECHNICAL FIELD

The present invention relates to a method for forming a substance layer and a method for manufacturing a device by employing the same, and more specifically, to a method for forming an epitaxial semiconductor layer and a method for manufacturing a semiconductor device by employing the same.

### BACKGROUND ART

As information and communication technology is advancing and demand for portable digital application devices such as smartphones, digital cameras, and tablet PCs is increasing, the semiconductor market is rapidly expanding. Semiconductor technology has secured growth momentum in the semiconductor market through scaling down integrated circuits over the past several decades. However, it is becoming increasingly difficult to secure technological competitiveness solely through technology which increases density or capacity through scaling down. Accordingly, research has recently been conducted to simultaneously improve device integration and to optimize performance through the development of substances and new manufacturing methods for three-dimensional device shape or high performance.

Meanwhile, various semiconductor substances are used in the manufacture of semiconductor devices, and depending on the composition and crystal structure of the substances, the performance or characteristics of the device may vary significantly. Furthermore, the characteristics of the device may be greatly influenced by the matching relationship or bonding characteristics between one substance layer and another substance layer adjacent to it. In particular, improvements in semiconductor substances having a single crystalline structure and the bonding interface formed thereby may be advantageous in securing excellent performance. However, the existing methods for growing single crystal semiconductors include a high-temperature vapor deposition method under the specific conditions or a method using molecular beams in a vacuum, which require high-temperature processes which place a thermal burden on the underlying layer or has limitations requiring a vacuum process.

Therefore, a manufacturing technology which may easily form a substance film with a single crystalline structure having excellent properties under various conditions and environments is desirable. In particular, this manufacturing technology may be advantageous for improving device performance and improving economic efficiency of manufacturing.

### DISCLOSURE OF THE INVENTION

### Technical Problem

The technological object to be achieved by the present invention is to provide a method for forming an epitaxial semiconductor layer which may easily form a single crystalline semiconductor layer having excellent properties under various conditions and situations without heating the substrate to a high temperature or using a vacuum state.

In addition, the technological object to be achieved by the present invention is to provide a method for manufacturing a semiconductor device having excellent performance by applying the above-described method for forming an epitaxial semiconductor layer.

The objects to be solved by the present invention are not limited to the objects mentioned above, and other objects not mentioned will be clearly understood by those skilled in the art from the description below.

### Technical Solution

According to embodiments of the present invention for achieving the above objects, there is provided a method for forming an epitaxial semiconductor layer comprising: a step for providing a crystallization base member having a single crystal structure; a step for forming a semiconductor layer having one of an amorphous structure and a polycrystalline structure in contact with the crystallization base member; a step for forming a heating layer which may be heated by a laser on the semiconductor layer; a step for melting the semiconductor layer by heating the heating layer by irradiating a laser to the heating layer; and a step for forming a single crystallized epitaxial semiconductor layer from the semiconductor layer through single crystallization of the semiconductor layer according to the single crystalline structure of the crystallization base member by cooling the molten semiconductor layer.

The crystallization base member may include any one of a single crystal silicon, a single crystal silicon germanium, and a single crystal germanium.

The semiconductor layer may include any one of a silicon, a silicon germanium, a germanium, a silicon carbide, GaAs, InGaAs, InAs, and InSb.

The heating layer may include at least one of metal and metal compounds.

The heating layer may include at least any one of TiN, Ti, TiSi, Ta, TaN, Co, CoSi, Ni, NiSi, Ru, W, WSi, Cu, Re, Mo, Nb, and Cr.

The heating layer may have a thickness of about 30 Å to 4,0000 Å.

The laser irradiated to the heating layer may have a wavelength of 0.02 μm to 11 μm.

In the step for melting the semiconductor layer, the laser irradiation time may be on the order of several ps to tens of μs.

The method may further include a step for forming a passivation layer on the heating layer.

The laser may be irradiated to the heating layer through the passivation layer.

The passivation layer may be an insulating layer containing an inorganic substance.

The crystallization base member may be a substrate member, a mask layer having at least one opening exposing a portion of the crystallization base member may be formed on the crystallization base member, and the semiconductor layer may be formed to fill the opening on the crystallization base member exposed by the opening.

The semiconductor layer may be formed to have the same thickness as the mask layer, or the semiconductor layer may be formed to have a thickness larger than the mask layer so as to cover the upper surface of the mask layer.

The crystallization base member may be disposed on an underlying layer, the crystallization base member may be formed to have a patterned layer structure having at least one opening exposing a portion of the underlying layer, and the semiconductor layer may be formed to fill the opening on the underlying layer exposed by the opening.

The semiconductor layer may be formed to have the same thickness as the crystallization base member, or the semiconductor layer may be formed to have a thickness larger than that of the crystallization base member to cover the upper surface of the crystallization base member.

According to another embodiment of the present invention, there is provided a method for manufacturing a semiconductor device comprising: a step for forming an epitaxial semiconductor layer using the method described above; and a step for forming a semiconductor device including the epitaxial semiconductor layer.

According to another embodiment of the present invention, there is provided a method for manufacturing a semiconductor device comprising: a step for providing a crystallization base member having a single crystal structure; a step for forming a mask layer on the crystallization base member having at least one opening exposing a portion of the crystallization base member; a step for forming a semiconductor layer having any one of an amorphous structure and a polycrystalline structure to fill the opening on the crystallization base member exposed by the opening; a step for forming a heating layer which may be heated by a laser on the semiconductor layer; a step for melting the semiconductor layer by heating the heating layer by irradiating a laser to the heating layer; a step for forming a single crystallized epitaxial semiconductor layer from the semiconductor layer through single crystallization of the semiconductor layer according to the single crystalline structure of the crystallization base member by cooling the molten semiconductor layer; and a step for forming a semiconductor device including the epitaxial semiconductor layer.

The semiconductor layer may be formed to have the same thickness as the mask layer, or the semiconductor layer may be formed to have a thickness larger than the mask layer so as to cover the upper surface of the mask layer.

The crystallization base member may include any one of a single crystal silicon, a single crystal silicon germanium, and a single crystal germanium.

The semiconductor layer may include any one of a silicon, a silicon germanium, a germanium, a silicon carbide, GaAs, InGaAs, InAs, and InSb.

The heating layer may include at least one of a metal and metal compounds.

The semiconductor device may include a transistor including the epitaxial semiconductor layer as an active layer.

According to another embodiment of the present invention, there is provided a method for manufacturing a semiconductor device comprising: a step for preparing a substrate structure in which a crystallization base member having a single crystalline structure is formed on an underlying layer, wherein the crystallization base member is formed in a patterned layer structure having at least one opening exposing a portion of the underlying layer; a step for forming a semiconductor layer having any one of an amorphous structure and a polycrystalline structure to fill the opening on the underlying layer exposed by the opening; a step for forming a heating layer which may be heated by a laser on the semiconductor layer; a step for melting the semiconductor layer by heating the heating layer by irradiating a laser to the heating layer; a step for forming a single crystallized epitaxial semiconductor layer from the semiconductor layer through single crystallization of the semiconductor layer according to the single crystalline structure of the crystallization base member by cooling the molten semiconductor layer; and a step for forming a semiconductor device including the epitaxial semiconductor layer.

The semiconductor layer may be formed to have the same thickness as the crystallization base member, or the semiconductor layer may be formed to have a thickness larger than that of the crystallization base member to cover the upper surface of the crystallization base member.

The crystallization base member may include any one of a single crystal silicon, a single crystal silicon germanium, and a single crystal germanium.

The semiconductor layer may include any one of a silicon, a silicon germanium, a germanium, a silicon carbide, GaAs, InGaAs, InAs, and InSb.

The heating layer may include at least one of a metal and metal compounds.

The semiconductor device may include a transistor including the epitaxial semiconductor layer as an active layer.

### Advantageous Effects

According to embodiments of the present invention, it is possible to implement a method for forming an epitaxial semiconductor layer which may easily form a semiconductor layer with a single crystalline structure having excellent characteristics under various conditions and situations without heating the substrate to a high temperature or using a vacuum state. In particular, an epitaxial semiconductor layer may be more easily formed in a completely different way from vapor deposition by using the melting and temperature profile of the semiconductor layer according to the indirect heating method using a laser.

A semiconductor device having excellent performance may be easily manufactured by applying the method for forming an epitaxial semiconductor layer according to the embodiments.

### BRIEF DESCRIPTION OF THE DRAWINGS

FIG. 1A to FIG. 1D are cross-sectional diagrams illustrating a method for forming an epitaxial semiconductor layer according to an embodiment of the present invention.

FIG. 2 is a cross-sectional diagram explaining a method for forming an epitaxial semiconductor layer according to another embodiment of the present invention.

FIG. 3 is a graph showing the results measuring the temperature of the sample surface upon laser irradiation in the process of forming an epitaxial semiconductor layer according to an embodiment of the present invention.

FIG. 4 is a graph showing the results measuring the temperature of the sample surface upon laser irradiation in the process according to the comparative example.

FIG. 5 is a graph illustrating the results evaluating the temperature profile of a sample when heated and cooled by laser irradiation in the process of forming an epitaxial semiconductor layer according to an embodiment of the present invention.

FIG. 6 is a graph illustrating the results evaluating the temperature profile of a sample during heating and cooling by laser irradiation in the process according to the comparative example.

FIG. 7 is a graph illustrating the results measuring the temperature change of the sample surface upon cooling after laser irradiation in the forming process of the epitaxial semiconductor layer according to an embodiment of the present invention.

FIG. 8 is a TEM (transmission electron microscopy) image showing the cross-sectional structure of samples used in the method for forming an epitaxial semiconductor layer according to an embodiment of the present invention.

FIG. 9 is a TEM image showing the microstructure of the semiconductor layer in samples used in the method for forming an epitaxial semiconductor layer according to an embodiment of the present invention.

FIG. 10 is a diagram showing the fast Fourier transform (FFT) analysis results obtained from TEM images of the semiconductor layer in samples used in the method for forming an epitaxial semiconductor layer according to an embodiment of the present invention.

FIG. 11A to FIG. 11F are cross-sectional diagrams for explaining a method for manufacturing a semiconductor device by applying the method for forming an epitaxial semiconductor layer according to an embodiment of the present invention.

FIG. 12A to FIG. 12D are cross-sectional diagrams for explaining a method of manufacturing a semiconductor device by applying a method for forming an epitaxial semiconductor layer according to another embodiment of the present invention.

FIG. 13A to FIG. 13F are cross-sectional diagrams for explaining a method for manufacturing a semiconductor device by applying a method for forming an epitaxial semiconductor layer according to another embodiment of the present invention.

FIG. 14A to FIG. 14D are cross-sectional diagrams for explaining a method for manufacturing a semiconductor device by applying a method for forming an epitaxial semiconductor layer according to another embodiment of the present invention.

FIG. 15 is a cross-sectional diagram illustrating a method for manufacturing a semiconductor device by applying a method for forming an epitaxial semiconductor layer according to another embodiment of the present invention.

### BEST MODE FOR CARRYING OUT THE INVENTION

Hereinafter, the embodiments of the present invention will be described in detail with reference to the accompanying drawings.

The embodiments of the present invention to be described below are provided to more clearly explain the present invention to those skilled in the art, and the scope of the present invention is not limited by the following embodiments, and the embodiments may be modified in many different forms.

The terms used in this specification are used to describe specific embodiments and are not intended to limit the present invention. The terms indicating a singular form used herein may include plural forms unless the context clearly indicates otherwise. Also, as used herein, the terms, “comprise” and/or “comprising” specify the presence of the stated shape, step, number, operation, member, element, and/or group thereof and does not exclude the presence or addition of one or more other shapes, steps, numbers, operations, elements, elements and/or groups thereof. In addition, the term, “connection” used in this specification means not only a direct connection of certain members, but also a concept including an indirect connection in which other members are interposed between the members.

In addition, in the present specification, when a member is said to be located “on” another member, this arrangement includes not only a case in which a member is in contact with another member, but also a case where another member exists between the two members. As used herein, the term, “and/or” includes any one and all combinations of one or more of the listed items. In addition, the terms of degree such as “about” and “substantially” used in the present specification are used as a range of values or degrees, or as a meaning close thereto, taking into account inherent manufacturing and substance tolerances, and exact or absolute figures provided to aid in the understanding of this application are used to prevent the infringers from unfairly exploiting the stated disclosure.

Hereinafter, embodiments of the present invention will be described in detail with reference to the accompanying drawings. A size or a thickness of areas or parts shown in the accompanying drawings may be slightly exaggerated for clarity of the specification and convenience of description. The same reference numbers indicate the same configuring elements throughout the detailed description.

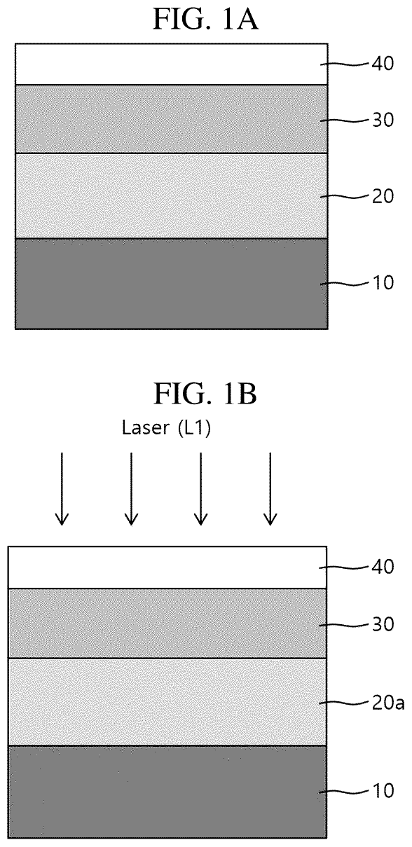

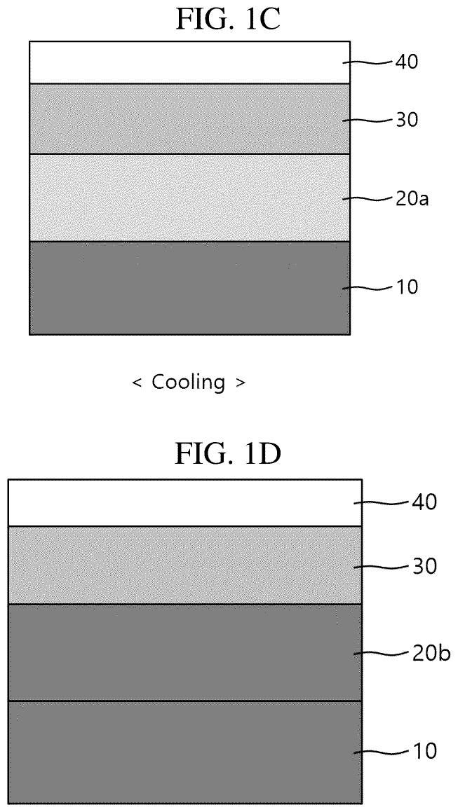

FIG. 1A to FIG. 1D are cross-sectional diagrams illustrating a method for forming an epitaxial semiconductor layer according to an embodiment of the present invention.

Referring to FIG. 1A, a crystallization base member 10 having a single crystalline structure may be prepared. The crystallization base member 10 may also be referred to as a ‘crystallization seed member’. The crystallization base member 10 may include any one of a single crystal silicon Si, a single crystal silicon germanium SiGe, and a single crystal germanium Ge. The crystallization base member 10 may be a single crystal substrate or a three-dimensional structure having a single crystal layer or single crystal surface formed on the surface of a certain substrate, but the present invention is not limited thereto. In FIG. 1A, a crystallization base member 10 of single crystalline structure having a flat surface which is a part of the structure is illustrated.

Next, the semiconductor layer 20 contacting with the crystallization base member 10, and having either an amorphous structure or a polycrystalline structure may be formed. The semiconductor layer 20 may include, for example, a group IV-based semiconductor such as a silicon Si, a silicon germanium SiGe, a germanium Ge, and a silicon carbide SiC, or may include group II-VI or group III-V semiconductors such as GaAs, InGaAs, InAs, and InSb. The thickness of the semiconductor layer 20 may be, for example, about 10 Å to 2,000 Å, but the embodiments of the present disclosure are not limited thereto.

A heating layer 30 which may be heated by a laser may be formed on the semiconductor layer 20. The heating layer 30 may include at least any one of a metal and metal compounds. For example, the heating layer 30 may include at least any one of TiN, Ti, TiSi, Ta, TaN, Co, CoSi, Ni, NiSi, Ru, W, WSi, Cu, Re, Mo, Nb, and Cr. It may be desirable for the heating layer 30 to have a thickness of about 30 Å to 4,000 Å to improve its function, but the present embodiment is not limited thereto, and the appropriate thickness of the heating layer 30 may vary depending on the cases. The heating layer 30 may have a high absorption rate for the laser and may serve to heat and melt the semiconductor layer 20 by absorbing the laser, and may also serve as a capping layer which traps the heat transferred to the semiconductor layer 20 or radiated from the heated semiconductor layer 20 toward the semiconductor layer 20. In this regard, the heating layer 30 may be referred to as a ‘laser absorption layer (a high absorption layer)’, a ‘thermal capping layer’, or a ‘heat transfer layer’.

The heating layer 30 may serve to suppress side effects such as deformation of the surface of the semiconductor layer 20 or the occurrence of protrusions on the surface of the semiconductor layer 20 in the subsequent heating process by laser irradiation. As the heating layer 30 may have a higher melting point than the semiconductor layer 20, even if the semiconductor layer 20 melts in the subsequent process, the heating layer 30 does not melt and its structure (a layer structure) may be maintained.

Furthermore, a passivation layer 40 may be further formed on the heating layer 30. The passivation layer 40 may be an insulating layer containing an inorganic substance or an insulating layer based on an inorganic substance. For example, the passivation layer 40 may include at least any one of a silicon oxide (SiO₂), a silicon nitride (SiₓN_{y}), and silicon nitride (SiON). For example, the passivation layer 40 may have a thickness of approximately 10 Å to 500 Å. The passivation layer 40 may serve to prevent the heating layer 30 from deformation such as hilllock or pinholes on the surface of the heating layer 30 generated by thermal stress during laser irradiation. However, the formation of the passivation layer 40 is optional and the formation may be omitted.

Referring to FIG. 1B, the semiconductor layer 20 may be melted by heating the heating layer 30 by irradiating the laser L1 to the heating layer 30. For example, the semiconductor layer 20 may melt as the temperature of the semiconductor layer 20 rises to about 1,000° C. to 1,600° C. The reference number 20a indicates ‘molten semiconductor layer’. When the passivation layer 40 is formed, the laser L1 may pass through the passivation layer 40 and be irradiated to the heating layer 30. The intensity of the laser L1 irradiated to the heating layer 30 may be determined by considering the laser absorption rate or process conditions depending on the type of object to be processed.

The laser L1 irradiated to the heating layer 30 may have a wavelength of approximately 0.02 μm to 11 μm. When at least one of these conditions is satisfied, the heating layer 30 may be more easily heated by using the laser L1, and the semiconductor layer 20 in contact with it may be melted more easily by heating the heating layer 30. Meanwhile, in the step for melting the semiconductor layer 20, the irradiation time of the laser L1 may be on the order of several ps to tens of microseconds. However, the range of the irradiation time is exemplary and may vary depending on the case.

In the embodiment of the present invention, as the heating layer 30 is heated by laser L1 irradiation, and the semiconductor layer 20 is melted by heating the heating layer 30, when the semiconductor layer 20 is melted, the crystallization base member 10 may not melt. Therefore, the crystallization process on the semiconductor layer 20 may be performed while maintaining the single crystalline structure of the crystallization base member 10 without a high temperature heating process. When the semiconductor layer 20 is melted according to the heating method using the laser L1, an appropriate temperature profile may be applied in the thickness direction from the crystallization base member 10 to the heating layer 30 by controlling the intensity of the irradiated laser L1. For example, when the semiconductor layer 20 is melted, the temperature of the upper part of the semiconductor layer 20 may be relatively high, and the temperature of the lower part of the semiconductor layer 20 may be relatively low. In other words, the temperature of the upper part of the molten semiconductor layer 20a may be relatively higher than the temperature of the lower part. Furthermore, the temperature of the heating layer 30 may be higher than the temperature of the semiconductor layer 20a. The temperature of the crystallization base member 10 may be lower than the temperature of the semiconductor layer 20a.

Referring to FIGS. 1C and 1D, the molten semiconductor layer 20a is cooled so that a single-crystallize the semiconductor layer 20a may be formed according to the single crystalline structure of the crystallization base member 10, thereby producing an epitaxial single crystallization from the semiconductor layer 20a. An epitaxial semiconductor layer 20b may be formed. Crystallization may proceed as the molten semiconductor layer 20a is cooled, and at this time, crystallization may occur according to the single crystalline structure of the crystallization base member 10. As a result, the epitaxial semiconductor layer 20b having a single crystalline structure may be formed. If the crystallization base member 10 is a single crystal silicon and the semiconductor layer 20 is an amorphous silicon, the epitaxial semiconductor layer 20b may be a single crystal silicon, and there may not be a boundary between the crystallization base member 10 and the epitaxial semiconductor layer 20b. The method for forming the epitaxial semiconductor layer 20b according to this embodiment of the present invention may be called a so-called liquid phase epitaxial (LPE) growth method. Laser (L1 in FIG. 1B) irradiation and appropriate temperature control may be applied to this LPE growth method.

Furthermore, the cooling process in FIG. 1C may be a natural cooling process at a room temperature or similar temperature conditions after laser irradiation (L1 in FIG. 1B), but in some cases, the cooling process may be artificially controlled by controlling the temperature around the sample (i.e., the structure in FIG. 1C).

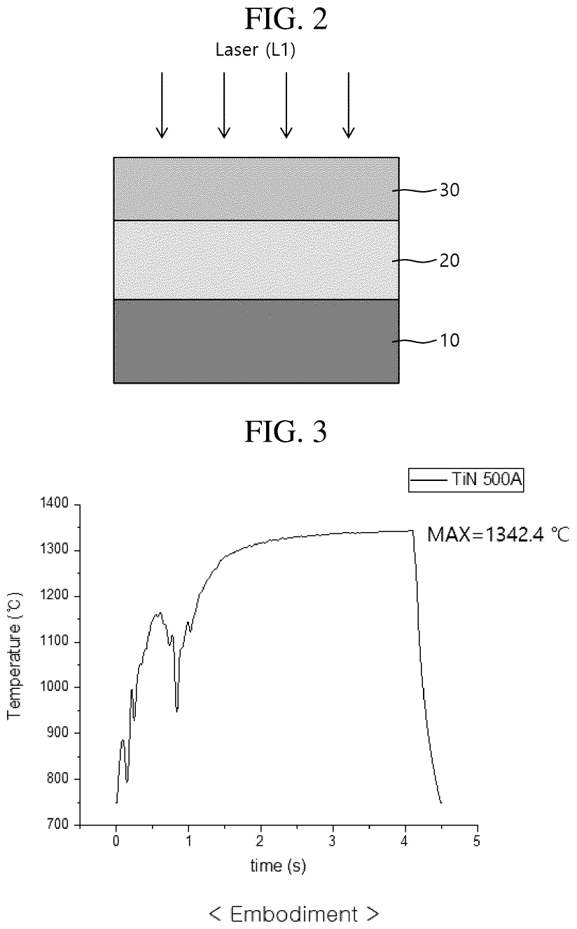

FIG. 2 is a cross-sectional diagram explaining a method for forming an epitaxial semiconductor layer according to another embodiment of the present invention.

Referring to FIG. 2, in another embodiment of the present invention, the laser L1 irradiation process may be performed without the passivation layer 40 of FIG. 1A. After forming the semiconductor layer 20 in contact with the crystallization base member 10 and forming the heating layer 30 in contact with the semiconductor layer 20, in the absence of a passivation layer (40 in FIG. 1A), a melting and crystallization process for the semiconductor layer 20 may be performed by irradiating the laser L1 to the heating layer 30. Accordingly, as described above, a single crystallized epitaxial semiconductor layer may be formed from the semiconductor layer 20 according to the crystallinity of the crystallization base member 10.

FIG. 3 is a graph showing the results measuring the temperature of the sample surface upon laser irradiation in the process for forming an epitaxial semiconductor layer according to an embodiment of the present invention. The sample according to this example includes a crystallization base member, a semiconductor layer, and a heating layer. Here, a TiN substance layer (thickness: 500 Å) was used as the heating layer. The crystallization base member was a single crystal silicon, and the semiconductor layer was an amorphous silicon (thickness: 2000 Å). While irradiating the laser toward the heating layer, the temperature change on the surface of the heating layer was measured over time.

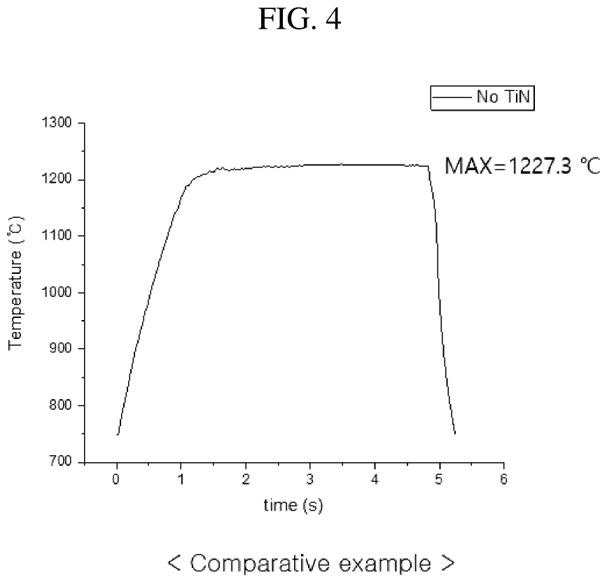

FIG. 4 is a graph showing the results measuring the temperature of the sample surface upon laser irradiation in the process according to the comparative example. The sample according to the comparative example includes a crystallization base member and a semiconductor layer, and does not include a heating layer (i.e., TiN substance layer) as in the embodiments. The above crystallization base member was a single crystal silicon, and the semiconductor layer was an amorphous silicon (thickness was approximately 2000 Å). While irradiating a laser toward the semiconductor layer, the temperature change of the surface of the semiconductor layer was measured over time.

As a result of comparing the results of FIGS. 3 and 4, the temperature of the sample (corresponding to FIG. 3) according to the example to which the heating layer (i.e., TiN substance layer) was applied was 1342.4° C., which is about 120° C. higher than that of the sample (corresponding to FIG. 4) according to the comparative example to which the heating layer was not applied. In addition, it may be seen that in connection with the rise time reaching to the maximum temperature, the sample according to the example (corresponding to FIG. 3) was shorter by more than 20% as compared to the sample according to the comparative example (corresponding to FIG. 4). Through these results, it may be seen that when the above-described heating layer is used, heating by converting the light energy of the incident laser into heat energy may be easily performed and thermal capping characteristics may be improved. Therefore, when using a heating layer, the epitaxial semiconductor layer according to an embodiment of the present invention may be easily formed.

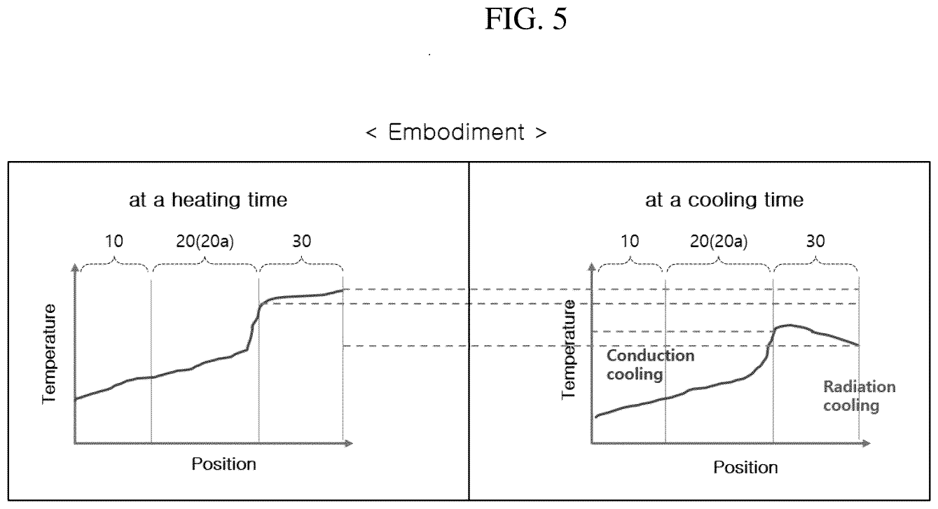

FIG. 5 is a graph illustrating the results evaluating the temperature profile of a sample when heated and cooled by laser irradiation in the process for forming an epitaxial semiconductor layer according to an embodiment of the present invention. The sample according to this example includes a crystallization base member 10, a semiconductor layer 20, and a heating layer 30. Here, a TiN substance layer was used as the heating layer 30. The crystallization base member 10 was a single crystal silicon, and the semiconductor layer 20 was and the temperature profile was evaluated while heating the sample by irradiating the laser toward the heating layer 30, and the temperature profile was evaluated while cooling after heating.

Referring to FIG. 5, it may be seen that the temperature of the heating layer 30 is the highest in the heating step. The temperature (an average temperature) of the semiconductor layer 20 was lower than the temperature of the heating layer 30, and the temperature (an average temperature) of the crystallization base member 10 was lower than the temperature (an average temperature) of the semiconductor layer 20. Furthermore, the temperature of the upper part of the semiconductor layer 20 was higher than the temperature of the lower part of the semiconductor layer 20. Accordingly, a melting process may proceed from a top of the semiconductor layer 20 to a bottom. Meanwhile, in the cooling step, radiation cooling may be performed on the surface of the heating layer 30, and conduction cooling may be performed on the crystallization base member 10. The temperature decrease at the interface between the heating layer 30 and the semiconductor layer 20a may occur relatively slowly.

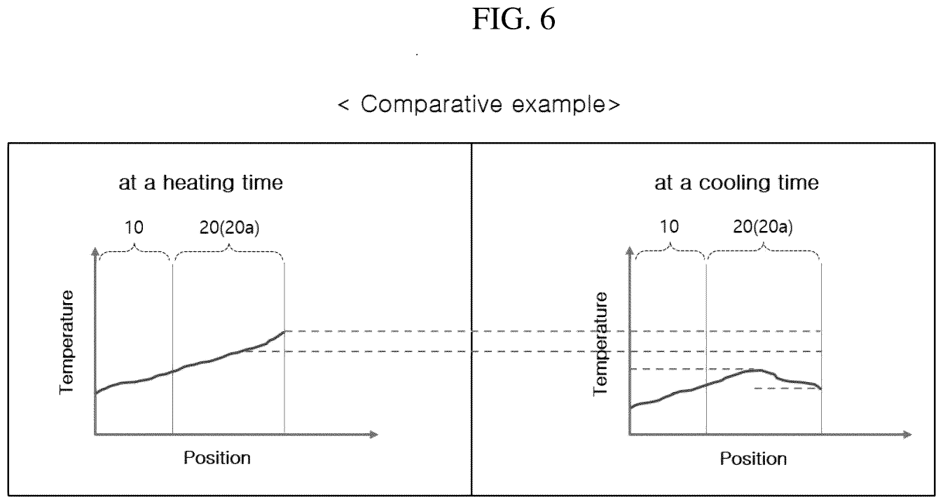

FIG. 6 is a graph illustrating the results evaluating the temperature profile of a sample during heating and cooling by laser irradiation in the process according to the comparative example. The sample according to the comparative example includes a crystallization base member 10 and a semiconductor layer 20, and does not include a heating layer (i.e., TiN substance layer) as in the example. The crystallization base member 10 was a single crystal silicon, and the semiconductor layer 20 was an amorphous silicon. The temperature profile was evaluated while heating the sample by irradiating the laser toward the semiconductor layer 20, and the temperature profile was evaluated while cooling after heating.

Referring to FIG. 6, it may be seen that in the sample according to the comparative example without using a heating layer, the temperature profile during heating and cooling is significantly different from the temperature profile in the sample according to the example described with reference to FIG. 5. Therefore, when using a heating layer, the epitaxial semiconductor layer may be easily formed.

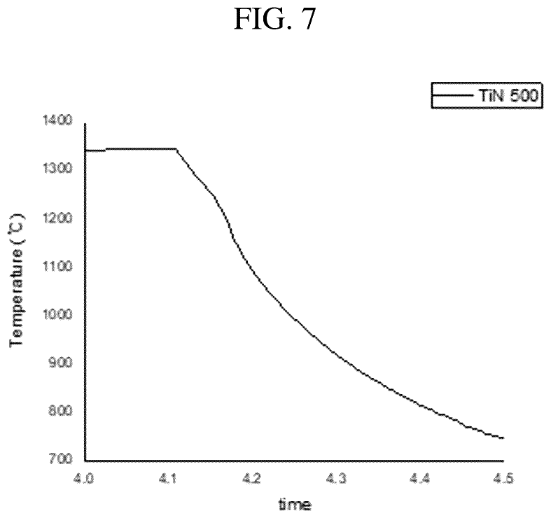

FIG. 7 is a graph illustrating the results measuring the temperature change of the sample surface upon cooling after laser irradiation in a process for forming the epitaxial semiconductor layer according to an embodiment of the present invention. The sample according to this example includes a crystallization base member, a semiconductor layer, and a heating layer. Here, a TiN substance layer (thickness: 500 Å) was used as the heating layer. The crystallization base member was a single crystal silicon, and the semiconductor layer was an amorphous silicon. The sample was heated by irradiating the laser toward the heating layer, and then the temperature change on the sample surface was measured over time after the laser was turned off.

Referring to FIG. 7, it may be seen that the temperature of the sample surface decreases relatively smoothly over time after the laser is turned off. Therefore, the molten semiconductor layer may be crystallized (single crystallized), for example, by gradually cooling from its lower part.

Table 1 below summarizes the results confirming whether the heating layer was applied and whether the epitaxial semiconductor layer was formed according to the thickness of the heating layer (i.e., whether the epitaxial process was successful). The case where TIN was used as a heating layer and the case where no heating layer was used (i.e., No TiN) were evaluated, the cases where the thickness of the heating layer (i.e., TiN layer) was 100 Å and 500 Å were evaluated, and the cases where the laser powers were 60 W, 120 W, and 250 W, were evaluated. The process conditions, including the power of the laser, are exemplary and the embodiments of the present invention are not limited thereto. The power of the laser may also vary depending on the temperature of the object to be processed.

TABLE 1

| | | |
|---|---|---|
| 60 W | 120 W | 250 W |

| | | |
|---|---|---|
| No TiN | | |
| TiN 100 Å | | Epitaxy |
| TiN 500 Å | Epitaxy | Epitaxy |

Referring to Table 1, the part written as Epitaxy indicates a case in which an epitaxial semiconductor layer is formed, and the blank space indicates a case in which an epitaxial semiconductor layer is not formed. If the laser power is too low, the epitaxial semiconductor layer may not be formed regardless of whether a heating layer is applied. In the case where a heating layer is not used (i.e., No TiN), it may be seen that even if the laser power is increased, the epitaxial semiconductor layer is not formed within the predetermined evaluated power range. It may be seen that when the thickness of the heating layer (i.e., TIN layer) is relatively thick, an epitaxial semiconductor layer may be easily formed at lower laser power compared to the case where the thickness of the heating layer (i.e., TiN layer) is relatively thin. This may be because the thicker the thickness of the heating layer is within a predetermined range, the easier it is to heat by laser absorption and the easier it is to control the cooling temperature profile. Therefore, when a heating layer of an appropriate thickness is used, an epitaxial semiconductor layer according to the embodiment may be formed more easily.

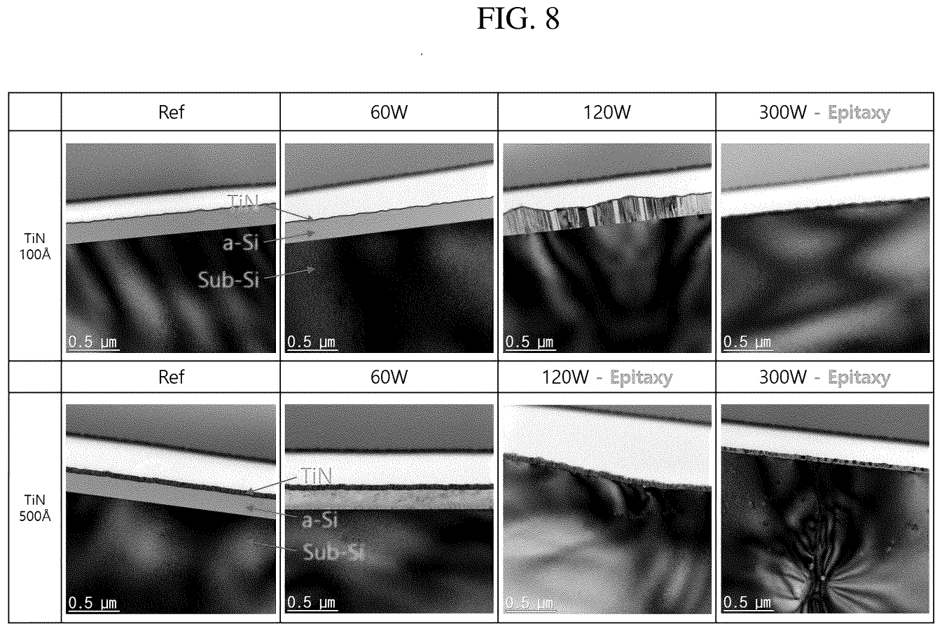

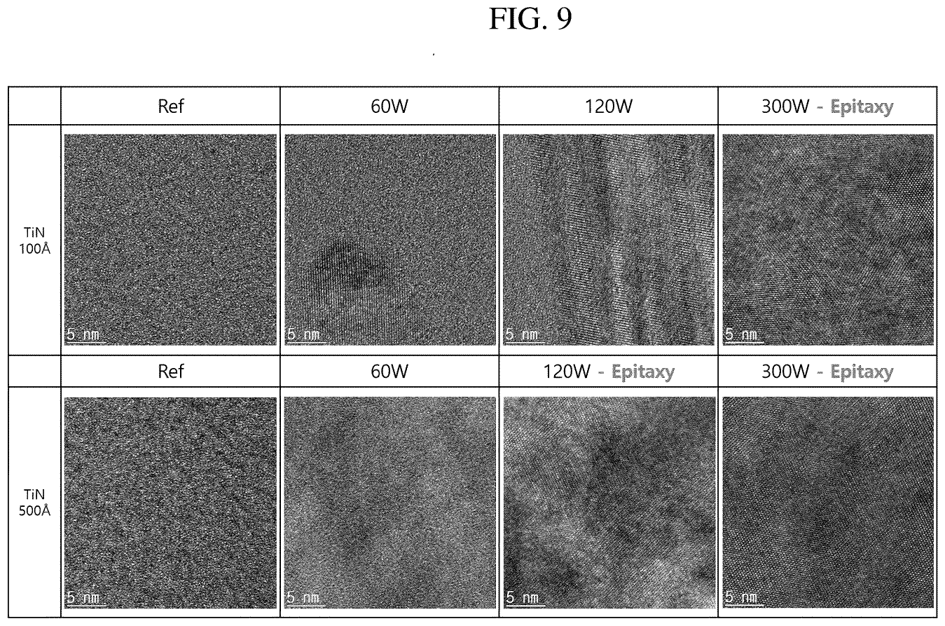

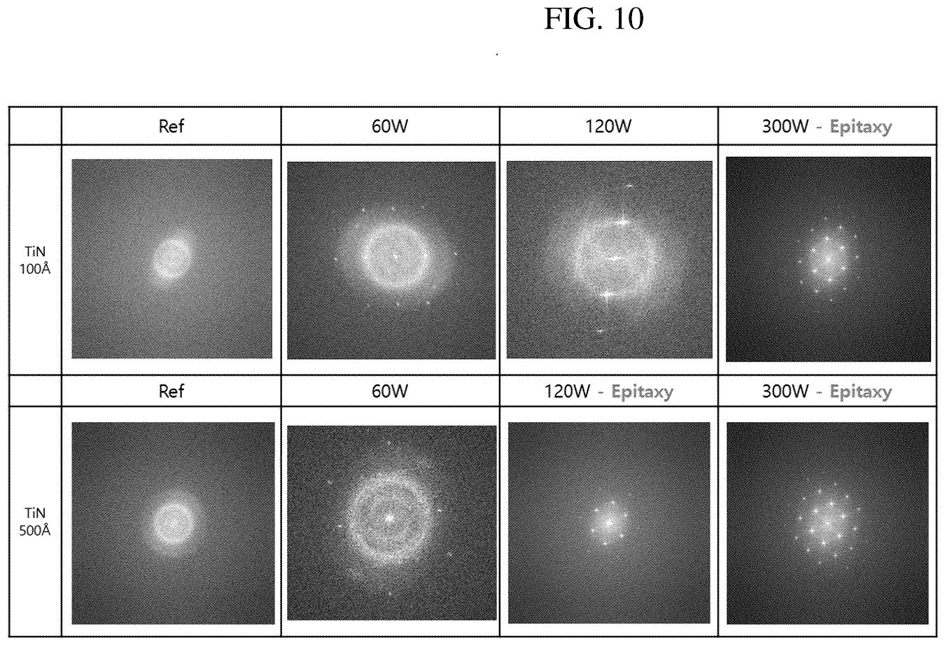

FIG. 8 is a TEM (transmission electron microscopy) image showing the cross-sectional structure of samples used in the method for forming an epitaxial semiconductor layer according to an embodiment of the present invention. The samples have a structure in which a semiconductor layer and a heating layer are formed sequentially on a crystallization base member. Here, the crystallization base member was a single crystal silicon (Sub-Si), the semiconductor layer was an amorphous silicon (a-Si), and the heating layer was a TiN layer. The cases where the thickness of the TiN layer is 100 Å and the case where the thickness is 500 Å are included. The laser power includes the cases of 60 W, 120 W, and 300 W, and Ref is the case where the laser was not irradiated. The part written as Epitaxy indicates the case where the epitaxial semiconductor layer is formed, and the rest indicates the case where the epitaxial semiconductor layer is not formed. These indications are the same in FIG. 9 and FIG. 10.

Referring to FIG. 8, as previously described in Table 1, it may be seen that when the thickness of the heating layer (i.e., TiN layer) is relatively thick, an epitaxial semiconductor layer may be easily formed at lower laser power as compared to the case where the thickness of the heating layer (i.e., TiN layer) is relatively thin. When the thickness of the TiN layer is 100 Å and a 300 W laser is used, since the semiconductor layer is single crystallized to become an epitaxial semiconductor layer, it may be confirmed that the boundary line in contact with the crystallization base member disappears. In addition, when the thickness of the TiN layer is 500 Å, since 120 W and 300 W lasers are used, the semiconductor layer is single crystallized to become an epitaxial semiconductor layer, it may be confirmed that the boundary line in contact with the crystallization base member disappears. FIG. 9 is a TEM image showing the microstructure of the semiconductor layer in samples used in the method for forming an epitaxial semiconductor layer according to an embodiment of the present invention.

Referring to FIG. 9, when the thickness of the TiN layer is 100 Å and a 300 W laser is used, as the semiconductor layer is single crystallized to become an epitaxial semiconductor layer, it may be seen that it exhibits a microstructure corresponding to a single crystal structure. In addition, when the thickness of the TiN layer is 500 Å, and 120 W and 300 W laser are used, as the semiconductor layer is single crystallized to become an epitaxial semiconductor layer, it may be confirmed that it exhibits a microstructure corresponding to a single crystal structure.

FIG. 10 is a diagram showing the results of fast Fourier transform (FFT) analysis obtained from TEM images of the semiconductor layer in samples used in the method for forming an epitaxial semiconductor layer according to an embodiment of the present invention.

Referring to FIG. 10, it may be confirmed that the semiconductor layers of certain samples were single crystallized from the FFT pattern.

The method for forming an epitaxial semiconductor layer according to embodiments of the present invention described above may be applied to the manufacturing methods of various semiconductor devices. For example, the method for forming an epitaxial semiconductor layer according to embodiments may be applied in place of existing gas phase epitaxy or molecular beam epitaxy, and in the situations or the conditions where it is difficult to apply existing gas phase epitaxy or molecular beam epitaxy, it may be usefully applied. A method for manufacturing a semiconductor device according to an embodiment of the present invention may include a step for forming an epitaxial semiconductor layer by a method according to the above-described embodiment and a step for forming a semiconductor device including the epitaxial semiconductor layer.

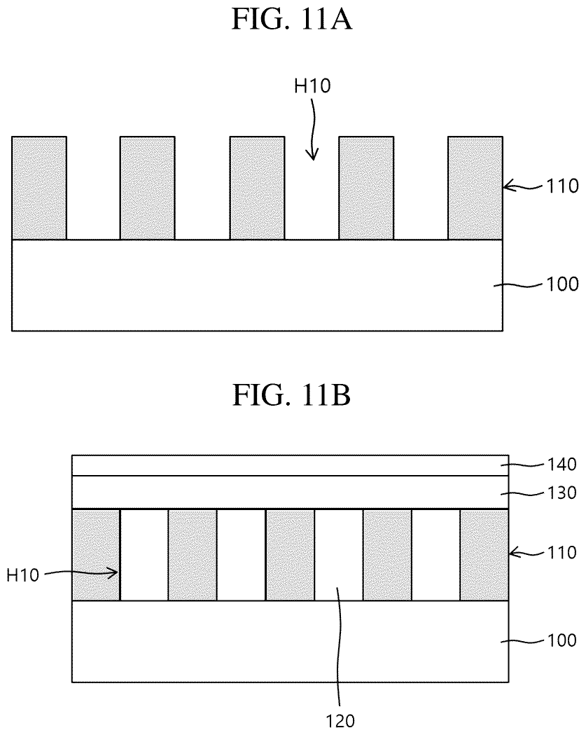

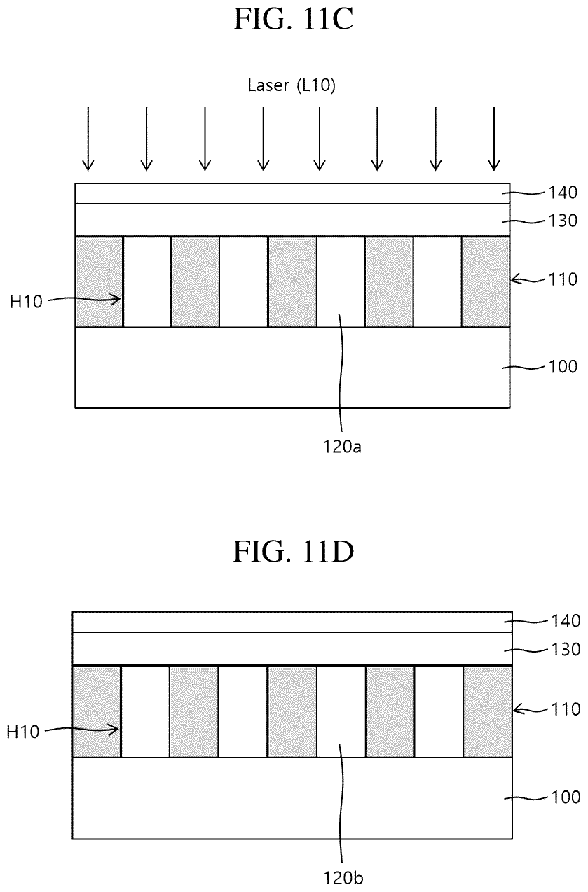

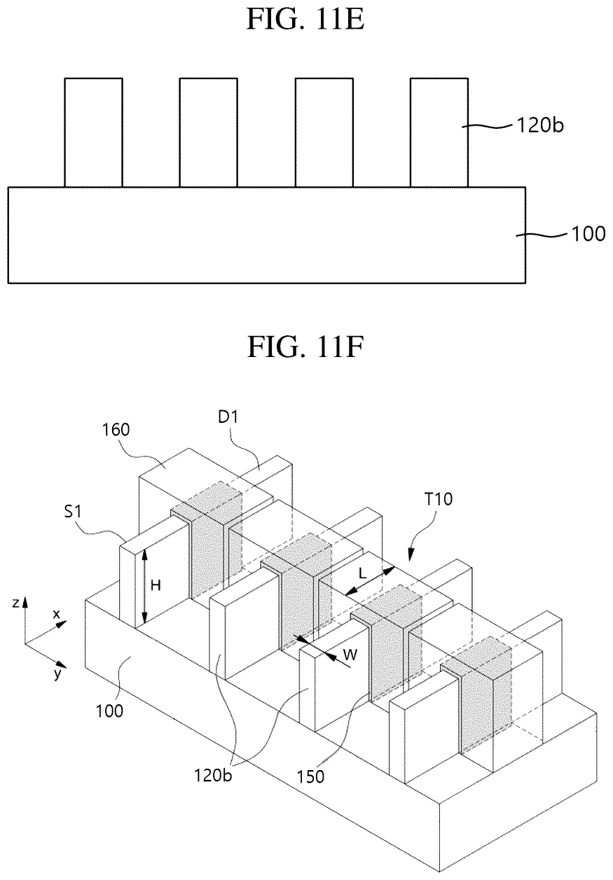

FIG. 11A to FIG. 11F are cross-sectional diagrams for explaining a method for manufacturing a semiconductor device by applying the method for forming an epitaxial semiconductor layer according to an embodiment of the present invention.

Referring to FIG. 11A, a crystallization base member 100 having a single crystalline structure may be prepared. The substance of the crystallization base member 100 may correspond to the crystallization base member 10 of FIG. 1A. The crystallization base member 100 may include any one of a single crystal silicon Si, a single crystal silicon germanium SiGe, and a single crystal germanium Ge. Here, the crystallization base member 100 may be any structure having a crystal surface for epitaxial crystallization of the semiconductor layer 20, and may be considered as a type of substrate member.

Next, a mask layer 110 having at least one opening H10 exposing a portion of the crystallization base member 100, that is, a single crystal surface may be formed on the crystallization base member 100. The mask layer 110 may be formed by a predetermined insulating substance and may have a higher melting point than that of the semiconductor layer (120 in FIG. 11B) to be formed subsequently.

Referring to FIG. 11B, a semiconductor layer 120 having either an amorphous structure or a polycrystalline structure may be formed to fill the opening H10 on the crystallization base member 100 exposed by the opening H10. The substance of the semiconductor layer 120 may correspond to the substance of the semiconductor layer 20 of FIG. 1A. The semiconductor layer 120 includes, for example, a group IV-based semiconductor such as silicon Si, silicon germanium SiGe, germanium Ge, and silicon carbide SiC, or may include group II-VI or group III-V semiconductors such as GaAs, InGaAs, InAs, and InSb. That is, the semiconductor layer 120 may include any one of silicon Si, silicon germanium SiGe, germanium Ge, silicon carbide SiC, GaAs, InGaAs, InAs, and InSb. In one embodiment, the semiconductor layer 120 may be doped with any impurity which determines the type of semiconductor. The semiconductor layer 120 may be formed through chemical vapor deposition or atomic layer deposition, as is well known in the art, but the present invention is not limited thereto.

Next, a heating layer 130 which may be heated by a laser may be formed on the semiconductor layer 120. The substance of the heating layer 130 may correspond to the substance of the heating layer 30 of FIG. 1A. The heating layer 130 may include at least one of a metal and metal compounds. For example, the heating layer 130 may include at least one of TIN, Ti, TiSi, Ta, TaN, Co, CoSi, Ni, NiSi, Ru, W, WSi, Cu, Re, Mo, Nb, and Cr. It may be desirable for the heating layer 130 to have a thickness of about 30 Å to 4,0000 Å to improve its function, but the present embodiment is not limited thereto.

In one embodiment, the heating layer 130 may continuously cover the semiconductor layer 120 in common across the semiconductor layer 120 having regions separated from each other by the mask layer 110. In another embodiment, the heating layer 130 may be formed selectively and discretely or discontinuously only on each region of the semiconductor layer 120 exposed by the mask layer 110.

Furthermore, a passivation layer 140 may be further formed on the heating layer 130. The passivation layer 140 may be an insulating layer containing an inorganic substance or an insulating layer based on an inorganic substance. For example, the passivation layer 140 may include at least one of silicon oxide SiO₂, silicon nitride SiₓN_{y}, and silicon nitride SiON. For example, the passivation layer 140 may have a thickness of about 50 Å to 500 Å. However, the formation of the passivation layer 140 is optional, and in some cases, it may not be formed.

Referring to FIG. 11C, the semiconductor layer 120 may be heated and melted by irradiating the laser L10 to heat the heating layer 130. The reference number 120a indicates ‘a molten semiconductor layer’. When the passivation layer 140 is formed, the laser L10 may pass through the passivation layer 140 and be irradiated to the heating layer 130. The laser L10 irradiated to the heating layer 130 may have a wavelength of approximately 0.02 μm to 11 μm. In the step for melting the semiconductor layer 120, the irradiation time of the laser L10 may be, for example, about several ps to several tens of μs.

Next, the molten semiconductor layer 120a is cooled to single-crystallize the semiconductor layer 120a according to the single crystalline structure of the crystallization base member 100, thereby single crystallizing the semiconductor layer 120a. As a result, as shown in FIG. 11D, the epitaxial semiconductor layer 120b may be formed.

Subsequently, a single crystalline structure as shown in FIG. 11E may be obtained by removing the passivation layer 140 and the heating layer 130 and selectively removing the mask layer 110. Referring to FIG. 11E, a patterned epitaxial semiconductor layer 120b may be disposed on the crystallization base member 100. For example, a plurality of epitaxial semiconductor layers 120b may be vertically disposed on the upper surface of the crystallization base member 100.

Next, a semiconductor device including the epitaxial semiconductor layer 120b may be formed. For example, as shown in FIG. 11F, a transistor T10 including the epitaxial semiconductor layer 120b as an active layer may be manufactured. Referring to FIG. 11F, a gate insulating layer 150 may be formed to cover the central portion of the epitaxial semiconductor layer 120b, and a gate electrode 160 may be formed on the gate insulating layer 150. The regions of the epitaxial semiconductor layer 120b on both sides of the gate electrode 160 may function as a source region S1 and a drain region D1, respectively. The central portion of the epitaxial semiconductor layer 120b surrounding the gate electrode 160 may function as a channel region. Although not shown in FIG. 11F, a predetermined device isolation region may be further formed inside the region of the crystallization base member 100 between the plurality of epitaxial semiconductor layers 120b. The transistor T10 shown in FIG. 11f may be said to have a type of fin field effect transistor (FET) structure.

The transistor T10 may exhibit excellent operating characteristics depending on the substance composition or crystallization state of the epitaxial semiconductor layer 120b. For example, when the epitaxial semiconductor layer 120b has a single crystalline structure and is a strained substance layer, the transistor T10 may exhibit excellent operating characteristics. If the substance of the epitaxial semiconductor layer 120b and the substance of the crystallization base member 100 are different from each other, strain may occur in the epitaxial semiconductor layer 120b during the crystallization (single crystallization) process of the epitaxial semiconductor layer 120b due to the difference in lattice constant between them.

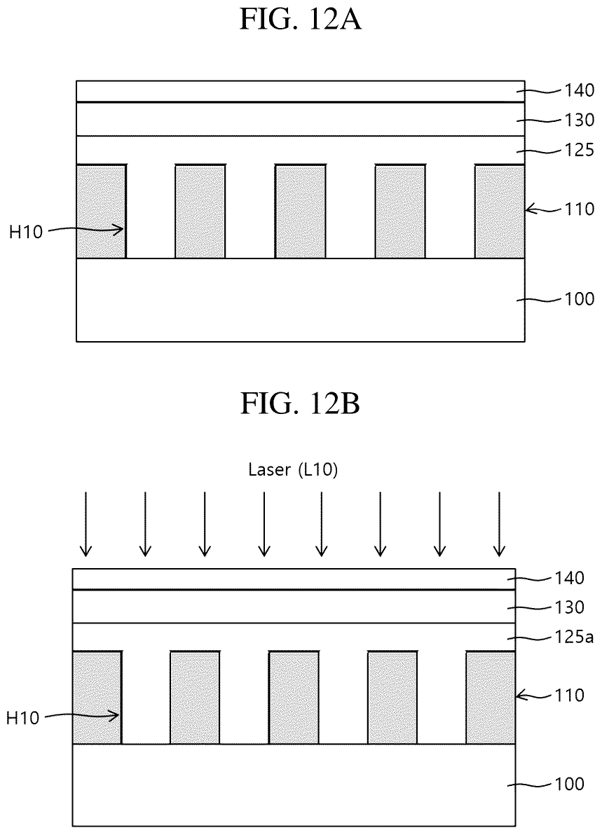

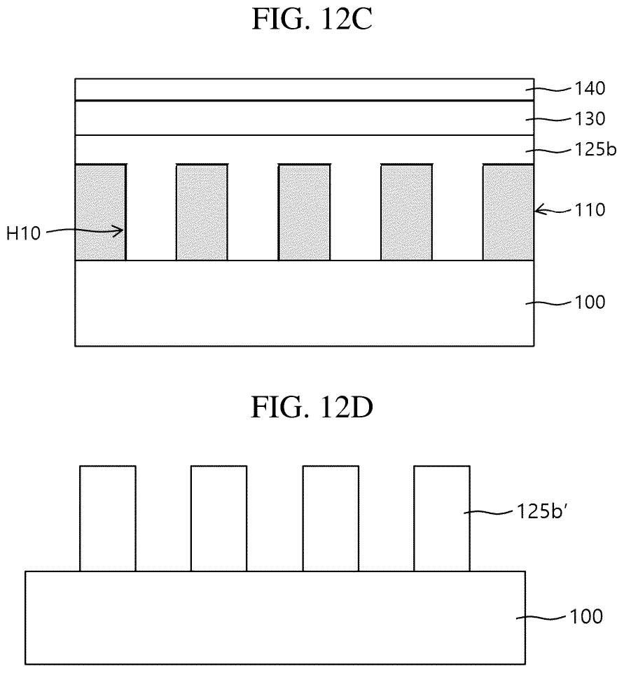

In the step of FIG. 11b, the semiconductor layer 120 is formed to have the same thickness (height) as the mask layer 110. However, according to another embodiment of the present invention, the semiconductor layer 120 may be formed to have a thickness deeper than that of the mask layer 110 so that the semiconductor layer 120 may cover the upper surface of the mask layer 110. An example is shown in FIGS. 12A to 12D.

FIG. 12A to FIG. 12D are cross-sectional diagrams for explaining a method for manufacturing a semiconductor device using a method of forming an epitaxial semiconductor layer according to another embodiment of the present invention.

Referring to FIG. 12A, a semiconductor layer 125 having either an amorphous structure or a polycrystalline structure may be formed to fill the opening H10 on the crystallization base member 100 exposed by the opening H10. At this time, the semiconductor layer 125 may be formed to have a thickness deeper than that of the mask layer 110 so as to cover the upper surface of the mask layer 110. Next, a heating layer 130 may be formed on the semiconductor layer 125, and optionally, a passivation layer 140 may be further formed on the heating layer 130.

Referring to FIG. 12B, the semiconductor layer 125 may be melted by heating the heating layer 130 by irradiating the laser L10 to the heating layer 130. The reference number 125a indicates ‘a molten semiconductor layer’.

Next, the molten semiconductor layer 125a is cooled to single-crystallize the semiconductor layer 125a according to the single crystalline structure of the crystallization base member 100, thereby single crystallizing the semiconductor layer 125a. As a result, as shown in FIG. 12C, the epitaxial semiconductor layer 125b may be formed.

Subsequently, after removing the passivation layer 140 and the heating layer 130, a structure as shown in FIG. 12D may be obtained by removing the upper layer of the epitaxial semiconductor layer 125b (i.e., the layer portion above 110) and selectively removing the mask layer 110. Referring to FIG. 12D, an epitaxial semiconductor layer 125b′ may be disposed on the crystallization base member 100. For example, a plurality of epitaxial semiconductor layers 125b′ may be vertically disposed on the upper surface of the crystallization base member 100.

Thereafter, although not shown, a semiconductor device including an epitaxial semiconductor layer 125b′ may be formed. For example, a transistor structure as shown in FIG. 11F may be manufactured.

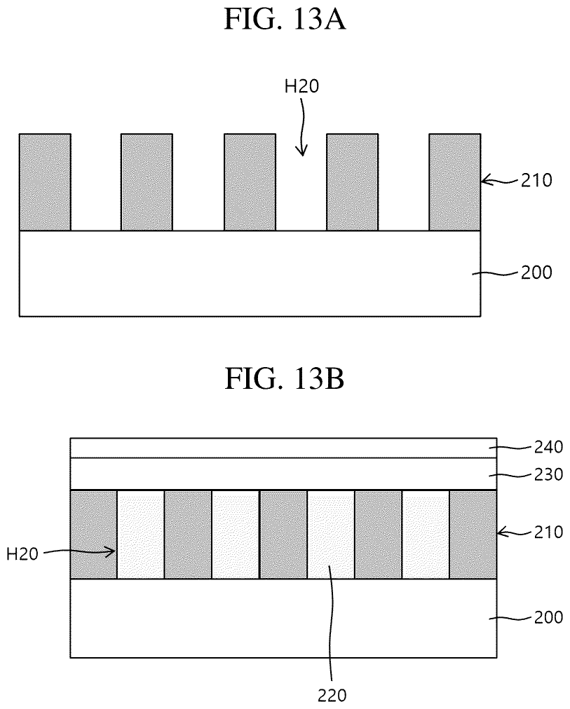

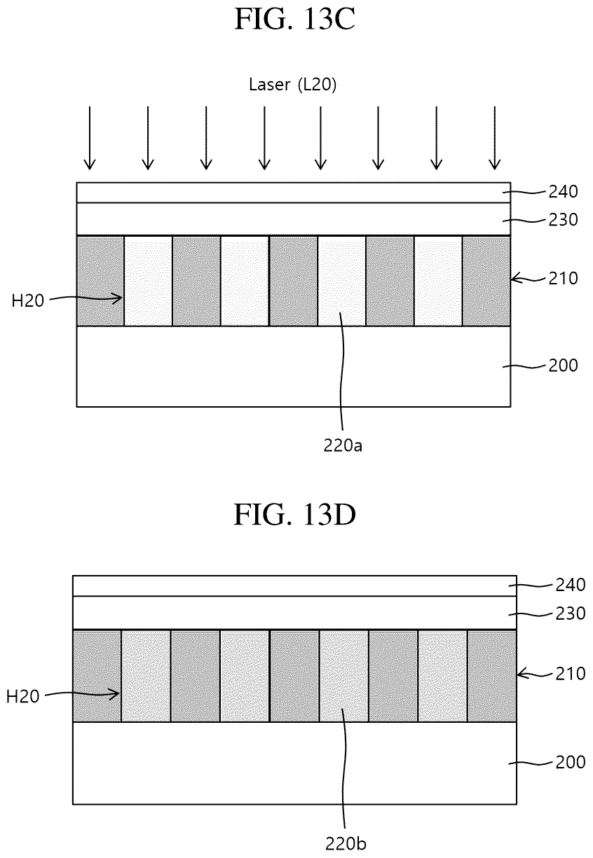

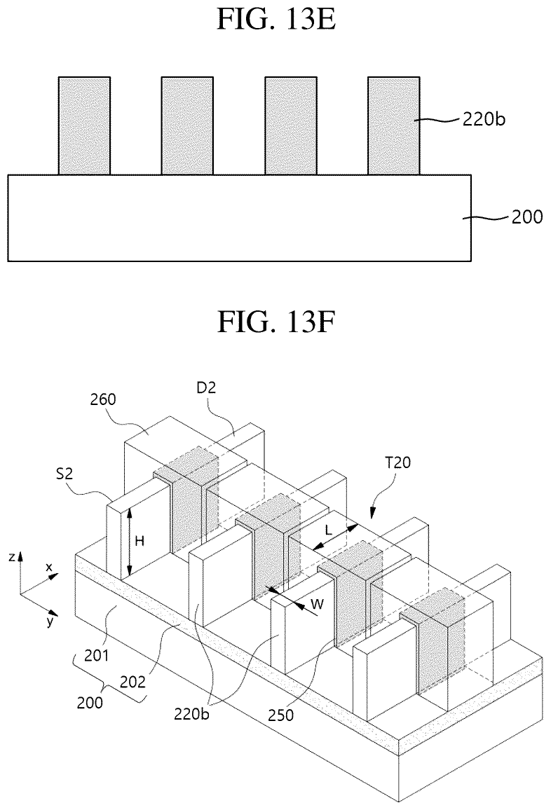

FIG. 13A to FIG. 13F are cross-sectional diagrams for explaining a method for forming a semiconductor device using a method of forming an epitaxial semiconductor layer according to another embodiment of the present invention.

Referring to FIG. 13A, a substrate structure in which a crystallization base member 210 having a single crystalline structure is formed on the underlying layer 200 may be prepared. The crystallization base member 210 may be formed as a patterned layer structure having at least one opening H20 which exposes a portion of the underlying layer 200. The underlying layer 200 may be a substrate member, and the crystallization base member 210 may be a type of mold structure.

The substance of the crystallization base member 210 may correspond to the crystallization base member 10 of FIG. 1A. The crystallization base member 210 may include any one of single crystal silicon Si, single crystal silicon germanium SiGe, and single crystal germanium Ge. For example, the underlying layer 200 may include an insulating substance layer, or may include an insulating substance layer and a semiconductor substance layer. When the underlying layer 200 includes the insulating substance layer and the semiconductor substance layer, the insulating substance layer may be disposed on the semiconductor substance layer, and the crystallization base member 210 may be disposed on the insulating substance layer. For example, the underlying layer 200 and the crystallization base member 210 may be obtained from a silicon-on-insulator (SOI) substrate.

Referring to FIG. 13b, the semiconductor layer 220 having either an amorphous structure or a polycrystalline structure may be formed to fill the opening H20 on the underlying layer 200 exposed by the opening H20. The substance of the semiconductor layer 220 may correspond to the substance of the semiconductor layer 20 of FIG. 1A. The semiconductor layer 220 includes, for example, a group IV-based semiconductor such as silicon Si, silicon germanium SiGe, germanium Ge, and silicon carbide SiC, or may include group II-VI or group III-V semiconductors such as GaAs, InGaAs, InAs, and InSb. In other words, the semiconductor layer 220 may include any one of silicon Si, silicon germanium SiGe, germanium Ge, silicon carbide SiC, GaAs, InGaAs, InAs, and InSb.

In this embodiment, the substance of the semiconductor layer 220 may be a different substance from the substance of the crystallization base member 210. The substance of the semiconductor layer 220 may be a substance with a lower melting point than that of the substance of the crystallization base member 210. For example, when the crystallization base member 210 is silicon Si, the semiconductor layer 220 may be silicon germanium SiGe or germanium Ge. However, the combination of the substance of the crystallization base member 210 and the substance of the semiconductor layer 220 may vary in various ways.

Next, a heating layer 230 which may be heated by a laser may be formed on the semiconductor layer 220. The heating layer 230 may be formed on the semiconductor layer 220 and the crystallization base member 210. The substance of the heating layer 230 may correspond to the substance of the heating layer 30 of FIG. 1A. The heating layer 230 may include at least one of a metal and metal compounds. For example, the heating layer 230 may include at least one of TiN, Ti, TiSi, Ta, TaN, Co, CoSi, Ni, NiSi, Ru, W, WSi, Cu, Re, Mo, Nb, and Cr. The heating layer 230 may preferably have a thickness of about 30 Å to 4,0000 Å, but the thickness thereof is not limited thereto.

Furthermore, a passivation layer 240 may be further formed on the heating layer 230. The passivation layer 240 may be an insulating layer containing an inorganic substance or an insulating layer based on an inorganic substance. For example, the passivation layer 240 may include at least one of silicon oxide SiO₂, silicon nitride SiₓN_{y}, and silicon nitride SiON. For example, the passivation layer 240 may have a thickness of approximately 10 Å to 500 Å. However, the formation of the passivation layer 240 is optional, and in some cases, it may not be formed.

Referring to FIG. 13C, the semiconductor layer 220 may be melted by heating the heating layer 230 by irradiating the laser L20 to the heating layer 230. The reference number 220a indicates ‘a molten semiconductor layer’. At this time, since the semiconductor layer 220 may have a lower melting point than that of the crystallization base member 210, only the semiconductor layer 220 may be melted while the crystallization base member 210 is hardly melted. The laser L20 irradiated to the heating layer 230 may have a wavelength of approximately 0.02 μm to 11 μm. In the step for melting the semiconductor layer 220, the irradiation time of the laser L20 may be, for example, several ps to several tens of μs.

Next, the molten semiconductor layer 220a is cooled to single-crystallize the semiconductor layer 220a according to the single crystalline structure of the side surface of the crystallization base member 210, thereby singly crystallizing the semiconductor layer 220a along the horizontal direction. As a result, as shown in FIG. 13D, the epitaxial semiconductor layer 220b may be formed. The crystallization base member 210 may remain without being removed and operate as a partial configuration of the device. For example, it may be used as a source/drain region of a transistor, but the present invention is not limited to this.

Optionally, in a subsequent process, a structure as shown in FIG. 13E may be obtained by subsequently removing the passivation layer 240 and the heating layer 230 and selectively removing the crystallization base member 210. Referring to FIG. 13E, an epitaxial semiconductor layer 220b may be disposed on the underlying layer 200. For example, a plurality of epitaxial semiconductor layers 220b may be vertically disposed on the upper surface of the underlying layer 200.

Next, a semiconductor device including the epitaxial semiconductor layer 220b may be formed. For example, as shown in FIG. 13F, a transistor T20 including the epitaxial semiconductor layer 220b as an active layer may be manufactured. Referring to FIG. 13F, a gate insulating layer 250 may be formed to cover the central portion of the epitaxial semiconductor layer 220b, and a gate electrode 260 may be formed on the gate insulating layer 250. The regions of the epitaxial semiconductor layer 220b on both sides of the gate electrode 260 may function as a source region S2 and a drain region D2, respectively. The central portion of the epitaxial semiconductor layer 220b surrounding the gate electrode 260 may function as a channel region. Meanwhile, the underlying layer 200 may have a structure including, for example, a semiconductor substance layer 201 and an insulating substance layer 202 disposed on the semiconductor substance layer 201. The transistor T20 shown in FIG. 13F may be said to have a type of fin field effect transistor (FET) structure.

The transistor T20 may exhibit excellent operating characteristics depending on the substance composition or crystallization state of the epitaxial semiconductor layer 220b. For example, when the epitaxial semiconductor layer 220b has a single crystalline structure and is a strained substance layer, the transistor T20 may exhibit excellent operating characteristics. If the substance of the epitaxial semiconductor layer 220b and the substance of the crystallization base member 210 are different from each other, strain may occur in the epitaxial semiconductor layer 220b during the crystallization (single crystallization) process of the epitaxial semiconductor layer 220b due to the difference in lattice constant between them.

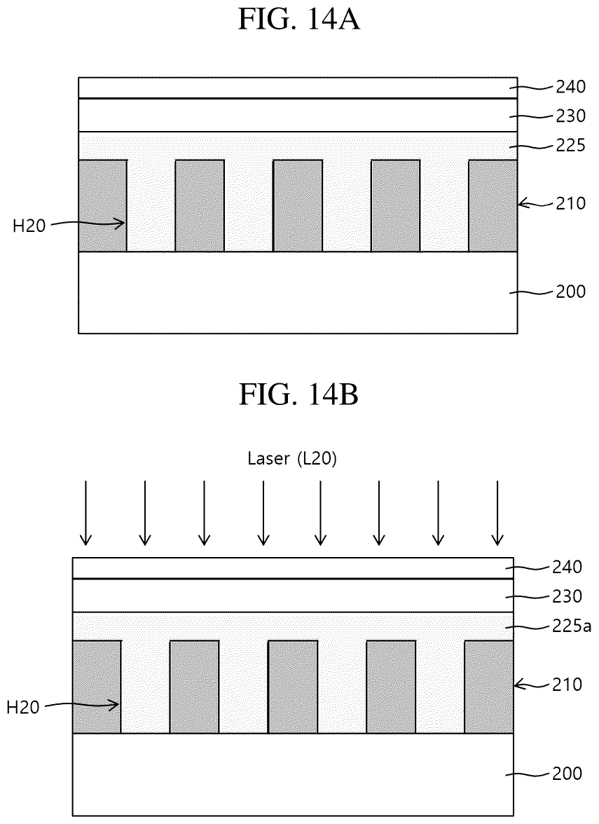

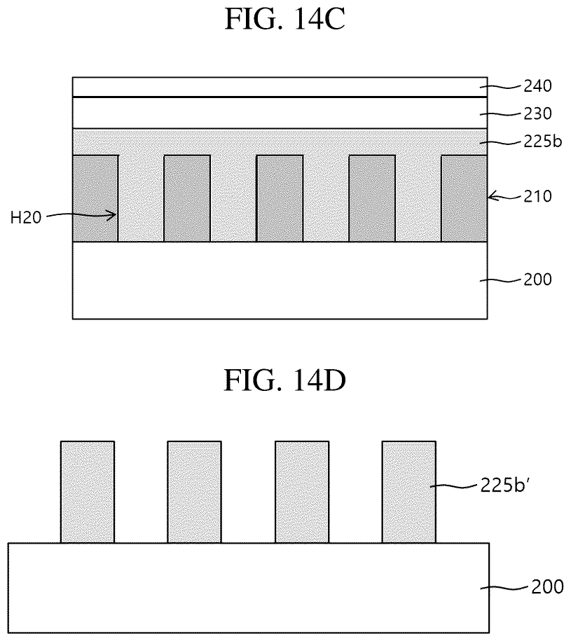

In the step of FIG. 13B, the semiconductor layer 220 was formed to the same thickness (height) as the crystallization base member 210. However, according to another embodiment of the present invention, the semiconductor layer 220 may be formed to have a thickness deeper than that of the crystallization base member 210 so that the semiconductor layer 220 may cover the upper surface of the crystallization base member 210. An example is shown in FIGS. 14A to 14D.

FIG. 14A to FIG. 14D are cross-sectional diagrams for explaining a method for manufacturing a semiconductor device by applying a forming method of an epitaxial semiconductor layer according to another embodiment of the present invention.

Referring to FIG. 14A, the semiconductor layer 225 having either an amorphous structure or a polycrystalline structure may be formed to fill the opening H20 on the underlying layer 200 exposed by the opening H20. At this time, the semiconductor layer 225 may be formed to have a thickness deeper than that of the crystallization base member 210 so as to cover the upper surface of the crystallization base member 210. Next, a heating layer 230 may be formed on the semiconductor layer 225, and optionally, a passivation layer 240 may be further formed on the heating layer 230.

Referring to FIG. 14b, the semiconductor layer 225 may be melted by heating the heating layer 230 by irradiating the laser L20 to the heating layer 230. The reference number 225a indicates ‘a molten semiconductor layer’.

Next, the molten semiconductor layer 225a is cooled to single-crystallize the semiconductor layer 225a according to the single crystalline structure of the crystallization base member 210, thereby single crystallizing the semiconductor layer 225a. As a result, as shown in FIG. 14C, the epitaxial semiconductor layer 225b may be formed.

Subsequently, after removing the passivation layer 240 and the heating layer 230, a structure as shown in FIG. 14D may be obtained by removing the upper layer (i.e., the layer portion above 210) of the epitaxial semiconductor layer 225b, and selectively removing the crystallization base member 210. Referring to FIG. 14D, an epitaxial semiconductor layer 225b′ may be disposed on the underlying layer 200. For example, a plurality of epitaxial semiconductor layers 225b′ may be vertically disposed on the upper surface of the underlying layer 200.

Thereafter, although not shown, a semiconductor device including an epitaxial semiconductor layer 225b′ may be formed. For example, a transistor structure as shown in FIG. 13f may be manufactured.

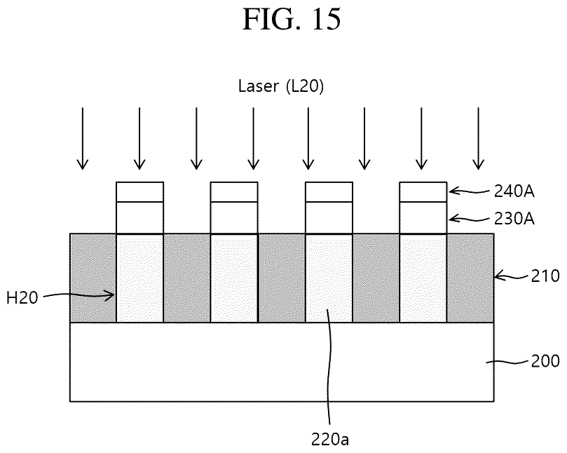

In the step of FIG. 13B, the heating layer 230 is formed on the semiconductor layer 220 and the crystallization base member 210, but according to another embodiment, the heating layer 230 may be formed only on the semiconductor layer 220 and may not be formed on the crystallization base member 210. An example is shown in FIG. 15.

FIG. 15 is a cross-sectional diagram illustrating a method of manufacturing a semiconductor device by applying a forming method of an epitaxial semiconductor layer according to another embodiment of the present invention.

Referring to FIG. 15, the heating layer 230A may have a patterned structure. The heating layer 230A may be formed on the semiconductor layer 220 and may not be formed on the crystallization base member 210. In this case, the passivation layer 240A also has a patterned structure and may be formed on the heating layer 230A. However, in some cases, the passivation layer 240A may not have a patterned structure, but may have a continuous layer structure to cover the heating layer 230A and the surrounding crystallization base member 210.

As shown in FIG. 15, when the heating layer 230A is formed on the semiconductor layer 220 and is not formed on the crystallization base member 210, the heating layer 230A may selectively perform a heating function only for the semiconductor layer 220. Accordingly, when the laser L20 is irradiated, the semiconductor layer 220 may be heated more easily by heating the heating layer 230A, and the crystallization base member 210 may be heated relatively less. Therefore, in this case, even if the substance of the semiconductor layer 220 and the substance of the crystallization base member 210 are similar or identical, the crystallization base member 210 may not be melted and only the semiconductor layer 220 may be selectively melted. As a result, epitaxial crystallization by melting and cooling of the semiconductor layer 220 may be more easily performed.

The method for manufacturing a semiconductor device according to the embodiments specifically described with reference to FIGS. 11A to 15 is illustrative, and the method for forming an epitaxial semiconductor layer according to the embodiments of the present application may be applied to a manufacturing process of various other devices. In addition to transistors, the method for forming an epitaxial semiconductor layer according to the embodiment may be applied to a manufacturing process of various devices such as memory devices, diodes, optical devices, and power devices.

As described above, according to embodiments of the present invention, it is possible to implement a method for forming an epitaxial semiconductor layer which may easily form a semiconductor layer of a single crystalline structure having excellent properties under various conditions and situations may be easily formed without heating the substrate to a high temperature or using a vacuum state. In particular, an epitaxial semiconductor layer may be more easily formed in a completely different way from vapor deposition by using the melting and temperature profile of the semiconductor layer according to the indirect heating method using a laser. If the method for forming an epitaxial semiconductor layer according to the above-described embodiments is applied, a semiconductor device having excellent performance may be easily manufactured.

In this specification, the preferred embodiments of the present invention have been disclosed, and although specific terms have been used, they are only used in a general sense to easily explain the technological content of the present invention and to help understanding the present invention, and they are not used to limit the scope of the present invention. It is obvious to those having ordinary skill in the related art to which the present invention belong that other modifications based on the technological idea of the present invention may be implemented in addition to the embodiments disclosed herein. It will be understood to those having ordinary skill in the related art that in connection with a method for forming an epitaxial semiconductor layer according to the embodiments described with reference to FIGS. 1A to 15 and a manufacturing method to which the above method is applied, various substitutions, changes, and modifications may be made without departing from the technological spirit of the present invention. Therefore, the scope of the invention should not be determined by the described embodiments, but should be determined by the technological concepts described in the claims.

The embodiments of the present invention may be applied to the manufacture of epitaxial semiconductor layers and semiconductor devices including the same. The method for forming an epitaxial semiconductor layer according to embodiments may be applied to a manufacture process of various devices such as transistors, memory devices, diodes, optical devices, and power devices.

1. A method for forming an epitaxial semiconductor layer comprising:
a step for providing a crystallization base member having a single crystal structure;
a step for forming a semiconductor layer having one of an amorphous structure and a polycrystalline structure in contact with the crystallization base member;
a step for forming a heating layer which may be heated by a laser on the semiconductor layer;
a step for melting the semiconductor layer by heating the heating layer by irradiating a laser to the heating layer; and
a step for forming a single crystallized epitaxial semiconductor layer from the semiconductor layer through single crystallization of the semiconductor layer according to the single crystalline structure of the crystallization base member by cooling the molten semiconductor layer.

2. The method for forming an epitaxial semiconductor layer of the claim 1, wherein the crystallization base member includes any one of a single crystal silicon, a single crystal silicon germanium, and a single crystal germanium.

3. The method for forming an epitaxial semiconductor layer of the claim 1, wherein the semiconductor layer includes any one of a silicon, a silicon germanium, a germanium, a silicon carbide, GaAs, InGaAs, InAs, and InSb.

4. The method for forming an epitaxial semiconductor layer of the claim 1, wherein the heating layer includes at least one of metal and metal compounds.

5. The method for forming an epitaxial semiconductor layer of the claim 4, wherein the heating layer includes at least any one of TiN, Ti, TiSi, Ta, TaN, Co, CoSi, Ni, NiSi, Ru, W, WSi, Cu, Re, Mo, Nb, and Cr.

6. The method for forming an epitaxial semiconductor layer of the claim 1, wherein the heating layer has a thickness of 0.02 μm to 11 μm.

7. The method for forming an epitaxial semiconductor layer of the claim 1, wherein the laser irradiated to the heating layer has a wavelength of 0.02 μm to 11/m.

8. The method for forming an epitaxial semiconductor layer of the claim 1, further comprising a step for forming a passivation layer on the heating layer, and wherein the laser is irradiated to the heating layer through the passivation layer.

9. (canceled)

10. The method for forming an epitaxial semiconductor layer of the claim 1,
wherein the crystallization base member is a substrate member,
wherein a mask layer having at least one opening exposing a portion of the crystallization base member is formed on the crystallization base member,
wherein the semiconductor layer is formed to fill the opening on the crystallization base member exposed by the opening.

11. The method for forming an epitaxial semiconductor layer of the claim 10, wherein the semiconductor layer is formed to have the same thickness as the mask layer, or the semiconductor layer is formed to have a thickness larger than the mask layer so as to cover the upper surface of the mask layer.

12. The method for forming an epitaxial semiconductor layer of the claim 1,
wherein the crystallization base member is disposed on an underlying layer,
wherein the crystallization base member is formed to have a patterned layer structure having at least one opening exposing a portion of the underlying layer,
wherein the semiconductor layer is formed to fill the opening on the underlying layer exposed by the opening.

13. The method for forming an epitaxial semiconductor layer of the claim 12, wherein the semiconductor layer is formed to have the same thickness as the crystallization base member, or the semiconductor layer is formed to have a thickness larger than that of the crystallization base member to cover the upper surface of the crystallization base member.

14. (canceled)

15. A method for manufacturing a semiconductor device comprising:
a step for providing a crystallization base member having a single crystal structure;
a step for forming a mask layer on the crystallization base member having at least one opening exposing a portion of the crystallization base member;
a step for forming a semiconductor layer having any one of an amorphous structure and a polycrystalline structure to fill the opening on the crystallization base member exposed by the opening;
a step for forming a heating layer which may be heated by a laser on the semiconductor layer;
a step for melting the semiconductor layer by heating the heating layer by irradiating a laser to the heating layer;
a step for forming a single crystallized epitaxial semiconductor layer from the semiconductor layer through single crystallization of the semiconductor layer according to the single crystalline structure of the crystallization base member by cooling the molten semiconductor layer; and
a step for forming a semiconductor device including the epitaxial semiconductor layer.

16. The method for manufacturing a semiconductor device of the claim 15, wherein the semiconductor layer is formed to have the same thickness as the mask layer, or the semiconductor layer is formed to have a thickness larger than the mask layer so as to cover the upper surface of the mask layer.

17. The method for manufacturing a semiconductor device of the claim 16,
wherein the crystallization base member includes any one of a single crystal silicon, a single crystal silicon germanium, and a single crystal germanium,
wherein the semiconductor layer includes any one of a silicon, a silicon germanium, a germanium, a silicon carbide, GaAs, InGaAs, InAs, and InSb.

18. (canceled)

19. The method for manufacturing a semiconductor device of the claim 15, wherein the semiconductor device includes a transistor including the epitaxial semiconductor layer as an active layer.

20. A method for manufacturing a semiconductor device comprising:
a step for preparing a substrate structure in which a crystallization base member having a single crystalline structure is formed on an underlying layer, wherein the crystallization base member is formed in a patterned layer structure having at least one opening exposing a portion of the underlying layer;
a step for forming a semiconductor layer having any one of an amorphous structure and a polycrystalline structure to fill the opening on the underlying layer exposed by the opening;
a step for forming a heating layer which may be heated by a laser on the semiconductor layer;
a step for melting the semiconductor layer by heating the heating layer by irradiating a laser to the heating layer;
a step for forming a single crystallized epitaxial semiconductor layer from the semiconductor layer through single crystallization of the semiconductor layer according to the single crystalline structure of the crystallization base member by cooling the molten semiconductor layer; and
a step for forming a semiconductor device including the epitaxial semiconductor layer.

21. The method for manufacturing a semiconductor device of the claim 20, wherein the semiconductor layer is formed to have the same thickness as the crystallization base member, or the semiconductor layer is formed to have a thickness larger than that of the crystallization base member to cover the upper surface of the crystallization base member.

22. The method for manufacturing a semiconductor device of the claim 20,
wherein the crystallization base member includes any one of a single crystal silicon, a single crystal silicon germanium, and a single crystal germanium,
wherein the semiconductor layer may include any one of a silicon, a silicon germanium, a germanium, a silicon carbide, GaAs, InGaAs, InAs, and InSb.

23. The method for manufacturing a semiconductor device of the claim 20, wherein the heating layer includes at least one of a metal and metal compounds.

24. (canceled)
